(19) United States
(12) Patent Application Publication
(10) Pub. No.: US 2010/0294536 A1
(43) Pub. Date: Nov. 25, 2010

(54) TRANSPARENT CONDUCTOR AND PRODUCTION METHOD THEREOF

(75) Inventor: Yoshihisa USAMI, Kanagawa (JP)

Correspondence Address: Studebaker & Brackett PC, One Fountain Square, 11911 Freedom Drive, Suite 750, Reston, VA, 20190, US

(73) Assignee: FUJIFILM CORPORATION, Tokyo (JP)

(21) Appl. No.: 12/787,003

(22) Filed: May 25, 2010

(30) Foreign Application Priority Data
May 25, 2009 (JP) 2009-125328

(51) Int. Cl. H01B 5/00; B05D 5/12

(52) U.S. Cl. 174/126.1; 427/108

(57) ABSTRACT

To provide a transparent conductor, containing: a convex-concave portion formed on a surface of a base such that a plurality of concave portions are aligned based on the surface; an auxiliary electrode layer formed of a conductive material, and provided at least on slant faces of the convex-concave portion; and a transparent conductive layer formed on surfaces of the convex-concave portion and the auxiliary electrode layer.

### BACKGROUND OF THE INVENTION

1. Field of the Invention

The present invention relates to a transparent conductor suitably used for a light emitting element, such as an organic electroluminescence element (Organic EL element), an inorganic electroluminescence element (inorganic EL element), and a light emitting diode (LED), and to a method for producing a transparent conductor.

2. Description of the Related Art

There have conventionally been demands for a transparent conductive film used as a light emitting element of organic EL elements, inorganic EL elements, LED, etc. to have both high conductivity and high transparency.

For example, in Japanese Patent Application Laid Open (JP-A) No. 05-151840, there is proposed a method for forming a metal auxiliary electrode on a transparent electrode by forming a transparent conductive film on a transparent insulating substrate, forming a transparent electrode having the predetermined shape by using an insulating mask having the predetermined shape, immersing in an electroless plating bath with the top face of the transparent electrode covered with the insulating mask so as to plate the exposed portions of the transparent electrode, releasing and removing the insulating mask.

However, in the method disclosed in JP-A No. 05-151840, the etched transparent conductive layer is masked, and partially plated so as to produce an auxiliary electrode. Therefore, this method does not partially form an auxiliary electrode in an efficient manner, and there is a waste of materials resulted from the patterning by the etching.

Moreover, in JP-A No. 2001-330728, there is proposed a wire-grid polarizer, in which thin metal lines are formed on a top of a convex portion and adjacent areas thereof by obliquely vacuum depositing a metal on a convex-concave structure formed on front and back surfaces of a substrate. In accordance with this proposal, excellent polarizing properties can be attained, but this document does not disclose nor suggest applying this polarizer to a transparent electrode. In fact, this proposal has not had any intention to simply and efficiently produce a transparent electrode of high conductivity without patterning.

### BRIEF SUMMARY OF THE INVENTION

The present invention aims to provide a transparent conductor, which has both high transparency and high conductivity, and improves light output efficiency when used as a light emitting element, and also aims to provide a method for producing a transparent conductor, which can efficiently produce the transparent conductor.

As a result of the diligent studies and researches conducted by the present inventors to achieve the aforementioned objects, the present inventors have come to the insights such that an auxiliary electrode layer can be partially formed, without patterning, by obliquely vacuum depositing a conductive material to a convex-concave portion, which has been formed by using a heat-mode material and directly writing with a laser beam, or by an imprint method, to thereby provide a transparent conductor having both high transparency and high conductivity as well as improving light output efficiency when the transparent conductor is used as a light emitting element.

The present invention is based upon the insights of the present inventors, and the means for solving the aforementioned problems are as follows:

<1> A transparent conductor, containing:

a convex-concave portion formed on a surface of a base such that a plurality of concave portions are aligned based on the surface;

an auxiliary electrode layer formed of a conductive material, and provided at least on slant faces of the convex-concave portion; and

a transparent conductive layer formed on surfaces of the convex-concave portion and the auxiliary electrode layer.

<2> The transparent conductor according to <1>, wherein the auxiliary electrode layer provided on the slant faces makes an acute angle of 0 degree to 45 degrees with respect to a vertical direction of the transparent conductor.
<3> The transparent conductor according to <1>, wherein a cross-sectional shape of the convex-concave portion is asymmetric.
<4> The transparent conductor according to <1>, wherein a planar shape of the convex-concave portion is either lines or a lattice.
<5> The transparent conductor according to <1>, wherein the transparent conductor satisfies the relationship: [(a/P)×100]≦50%, where a represents a flat width of the convex portion, and P represents a minimum distance between two convex portions adjacent to each other.
<6> The transparent conductor according to <1>, wherein the transparent conductive layer contains a conductive polymer.
<7> A method for producing a transparent conductor, containing:

aligning a plurality of convex portions based on a surface of a base so as to form a convex-concave portion on the surface of the base;

forming an auxiliary electrode layer formed of a conductive material at least on slant faces of the convex-concave portion; and

forming a transparent conductive layer on surfaces of the convex-concave portion and the auxiliary electrode layer.

<8> The method for producing a transparent conductor according to <7>, wherein the aligning comprises providing on the surface of the base an organic layer capable of changing a shape thereof in a heat mode, and exposing the organic layer to condensed light, so as to form the convex-concave portion.
<9> The method for producing a transparent conductor according to <7>, wherein the aligning comprises providing an imprint layer on the surface of the base, and pressing an imprint mold against the imprinting layer, so as to form the convex-concave portion in accordance with an imprint method.
<10> The method for producing a transparent conductor according to <9>, wherein the imprint mold is formed by etching through a mask, and the mask is an organic layer capable of changing a shape thereof in a heat mode and is provided with a convex-concave portion by being exposed to condensed light.
<11> The method for producing a transparent conductor according to <7>, wherein the formation of the auxiliary electrode layer is carried out by a vacuum deposition, and the vacuum deposition is carried out at an angle of 1 degree to 80 degrees with respect to a vertical direction of the base, with the base being placed so as to subject a side of the base where the convex-concave portion has been formed to the vacuum deposition

According to the present invention, the conventional problems in the art can be solved, and there can be provided a transparent conductor having high transparency and high conductivity as well as improved light output efficiency in the case of the transparent conductor serving as a light emitting element, and a method for producing a transparent conductor, which can efficiently produce the transparent conductor, as an auxiliary electrode layer can be partially formed by obliquely vacuum depositing a conductive material to a convex-concave portion without patterning.

### BRIEF DESCRIPTION OF THE DRAWINGS

FIG. 1 is a schematic diagram showing one example of a cross-sectional shape of a convex-concave portion.

FIG. 2 is a schematic diagram showing another example of a cross-sectional shape of a convex-concave portion.

FIG. 3 is a schematic diagram showing another example of a cross-sectional shape of a convex-concave portion.

FIG. 4 is a schematic diagram showing another example of a cross-sectional shape of a convex-concave portion.

FIG. 5A is a diagram showing one example of a surface of an organic layer as planarly seen.

FIG. 5B is a diagram showing another example of the surface of the organic layer as planarly seen.

FIG. 5C is a cross-sectional diagram showing one example of the organic layer provided with the concave portions and the base.

FIGS. 6A to 6C are diagrams showing the process for forming the convex-concave portion in accordance with an imprint method.

FIG. 7A is a schematic diagram showing the convex-concave portion forming step in the method for producing a transparent conductor of the present invention.

FIG. 7B is a schematic diagram showing the auxiliary electrode layer forming step in the method for producing a transparent conductor of the present invention.

FIG. 7C is a schematic diagram showing the transparent conductive layer forming step in the method for producing a transparent conductor of the present invention.

FIGS. 8A to 8C are schematic diagrams for explaining the convex-concave portion forming step and the auxiliary electrode layer forming step in Example 1.

FIG. 9 is a schematic diagram showing the state of the oblique vacuum deposition in the auxiliary electrode layer forming step in Example 1.

FIG. 10 is a schematic diagram showing the auxiliary electrode layers formed on the slant faces of the convex-concave portion in the auxiliary electrode layer forming step in Example 1.

FIG. 11 is a schematic diagram showing the state where a transparent conductive layer is formed in the transparent conductive layer forming step in Example 1.

### DETAILED DESCRIPTION OF THE INVENTION

### Transparent Conductor and Method for Producing Transparent Conductor

The transparent conductor of the present invention contains at least a convex-concave portion formed on a surface of a base such that a plurality of concave portions are aligned based on the surface, an auxiliary electrode layer formed of a conductive material, and provided at least on slant faces of the convex-concave portion, and may further contain other layers, as necessary.

The method for producing a transparent conductor of the present invention contains a convex-concave portion forming step, an auxiliary electrode layer forming step, and a transparent conductive layer forming step, and may further contain other steps, as necessary.

The transparent conductor of the present invention is more suitably produced by the method for producing a transparent conductor of the present invention.

The details of the transparent conductor of the present invention will be explained in the explanation of the method for producing a transparent conductor of the present invention, hereinafter.

In the transparent conductor of the present invention, the auxiliary electrode layer formed on the slant faces of the convex-concave portion preferable makes an acute angle of 0 degree to 45 degrees, more preferably 1 degree to 30 degrees, yet more preferably 5 degrees to 20 degrees, with the vertical direction of the transparent conductor.

When the angle is smaller than 0 degree, in the case where the convex-concave portion is formed by a transfer of the shape, it may be difficult to release from a mold. When the angle is larger than 45 degrees, the light transmittance of the transparent conductor may be decreased because of the auxiliary electrode layer.

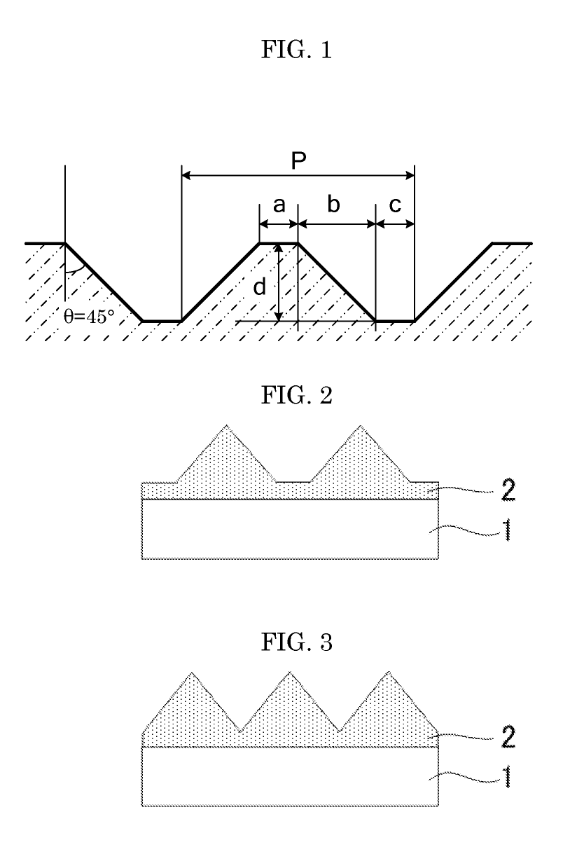

As shown in FIG. 1, the minimum distance (pitch) P between adjacent convex portions is preferably 10 nm to 10,000 nm, more preferably 100 nm to 1,000 nm.

Moreover, as also shown in FIG. 1, the ratio [(a/P)×100] of the flat width of the convex portion a to the pitch is preferably 50% or less, more preferably 25% or less, yet more preferably 10% or less, the most preferably 0%. When the ratio [(a/P)×100] is more than 50%, the conductive material is deposited onto the flat portion during the formation of the auxiliary electrode layer, leading to the decrease in the light transmittance of the transparent conductor.

Furthermore, as shown in FIG. 1, the ratio of [(b/P)×100] of the slant portion width b to the pitch P is preferably 0% to 50%. Moreover, the ratio [(c/P)×100] of the flat width of the bottom part c to the pitch P is preferably 0% to 100%. The ratio [(d/P)×100] of the height of the convex portion d to the pitch P is preferably 10% to 100%.

Accordingly, the cross-sectional shape of the convex-concave portion is preferably the cross-sectional shape shown in FIG. 2 (the flat width a of the convex portion is 0 nm), i.e. the shape such that there is no flat portion on the convex portion but on the bottom part in the convex-concave portion, rather than the cross-sectional shape shown in FIG. 3 (the flat width c of the bottom part is 0 nm), in view of high transmittance.

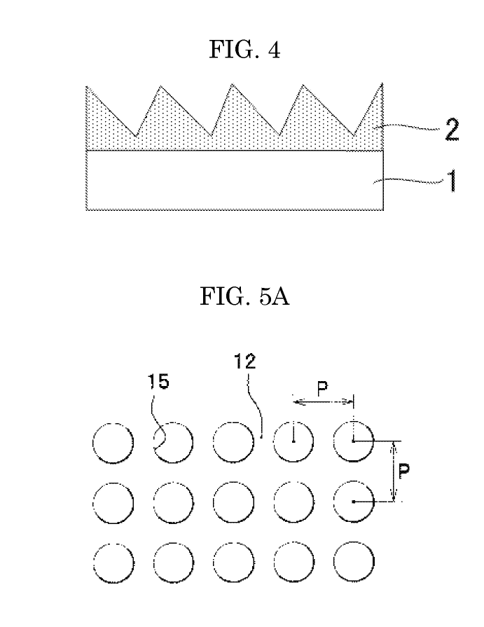

Moreover, the cross-sectional shape of the convex-concave portion is preferably asymmetric as shown in FIG. 4, not symmetric, because it can be easily released from the mold at the time of the transferring during the convex-concave forming step while maintaining the same degree in the easiness for forming the auxiliary electrode layer.

The cross-sectional shape of the convex-concave portion denotes, unless otherwise stated, a cross section (cross-sectional shape) in the aligned direction of the convex portions (the direction along which the convex portions are lined), and examples thereof include rectangle, triangle, and trapezoid.

The planar shape of the convex-concave portion as seen from the top may be lines, mesh, the shape where many hexagons are aligned, the shape where may triangles are aligned, the shape where many polygons are aligned, or stripes (lattice). Among the shapes listed above, the lines and lattice are particularly preferable, as they are easily formed, and the oblique vacuum deposition can be easily performed.

### <Convex-Concave Portion Forming Step>

The convex-concave portion forming step is aligning a plurality of convex portions based on a surface of a base so as to form a convex-concave portion on the surface of the base.

### —Base—

The base is suitably selected depending on the intended purpose without any restriction in terms of its material, shape, structure, size, and the like. For example, the material may be a metal, an inorganic material, or an organic material, the shape may be a plate shape, the structure may be a monolayer structure or a laminate structure, and the size can be suitably adjusted depending on the use or the like.

As the metal, transition metals are preferable. Examples of the transition metals include various metals such as Ni, Cu, Al, Mo, Co, Cr, Ta, Pd, Pt, Au, and alloys thereof.

Examples of the inorganic material include glass, silicon (Si), and quarts (SiO₂).

As the organic material, resins are preferable. Examples of the resins include polyethylene terephthalate (PET), polyethylene naphthalate (PEN), polycarbonate (PC), a low-melting point fluororesin, polymethyl methacylate (PMMA), and triacetate cellulose (TAC). Among them, PET, PC, and TAC are particularly preferable.

### —Formation of Convex-Concave Portion—

The convex-concave portion may be the one originally provided to a base, such as of silica clay, but it is preferred that a convex-concave portion be arbitrarily formed by photolithography or imprinting.

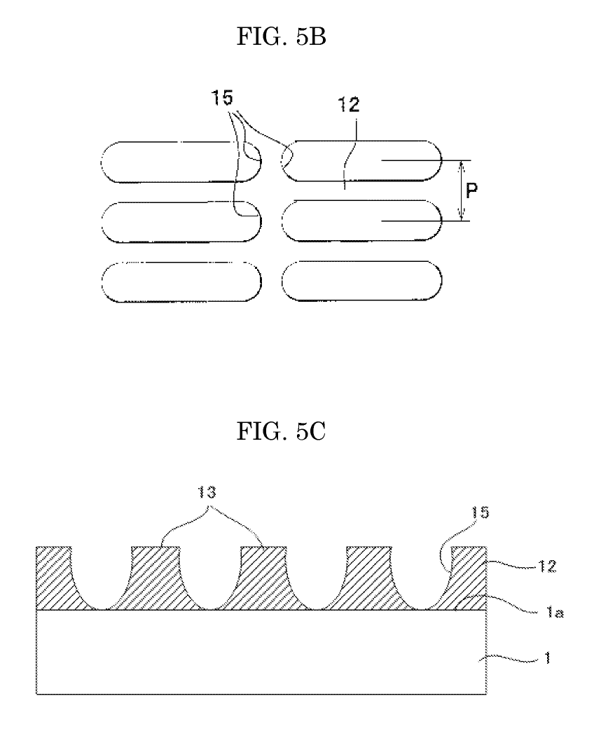

As shown in FIG. 5C, a plurality of the convex portions 13 and concave portions 15 is formed on one surface 1a of the substrate 1 at a constant pitch. In this case, the concave portions 13 and the convex portions 15 formed between a plurality of the convex portions 13 are determined as a convex-concave portion as a whole.

Note that, the cross-sectional shape of the convex-concave portion is not necessarily linear shape, and can be a shape with a curve(s).

For the formation of the convex-concave portion, the convex-concave portion may be formed by sand-bursting the base itself, but is preferably formed by a method in which a layer capable of forming a convex-concave portion (e.g., a heat-mode layer, an imprint layer, and a resist layer) on a base and the convex-concave portion is formed in such layer. Specific examples of such the method include: (1) a method in which an organic layer capable of forming its shape in heat mode is formed on one surface of a base, and is exposed to condensed light so as to form a convex-concave portion; (2) a method in which an imprint layer is formed on one surface of a base, and an imprint mold is pressed against the imprint layer so as to form a convex-concave portion in accordance with an imprint method; and (3) a method in which a resist layer is formed on one surface of a base, and a convex-concave portion is formed by photolithography.

### —Convex-Concave Forming Method (1)—

The organic layer capable of changing a shape thereof with heat is a layer capable of forming concave portions, in which the material thereof changes the shape thereof with heat converted from the strong light which has been applied to the layer. As the material for the organic layer, a cyanine-based compound, a phthalocyanine-based compound, a quinone-based compound, a squarylium-based compound, an azlenium-based compound, a thiol complex salt-based compound, a merocyanine-based compound or the like may be used, for example.

Preferred examples thereof include methine colorants (cyanine colorants, hemicyanine colorants, styryl colorants, oxonol colorants, merocyanine colorants, etc.), macrocyclic colorants (phthalocyanine colorants, naphthalocyanine colorants, porphyrin colorants, etc.), azo colorants (including azo metal chelate colorants), allylidene colorants, complex colorants, coumarin colorants, azole derivatives, triazine derivatives, 1-aminobutadiene derivatives, cinnamic acid derivatives and quinophthalone-based colorants. Among these, methine colorants and azo colorants are particularly preferable.

Regarding the organic layer, a colorant used therefor may be suitably selected according to the wavelength of a laser light source, and the structure thereof may be modified.

For example, when the oscillation wavelength of the laser light source is in the vicinity of 780 nm, selection of a colorant from pentamethine cyanine colorant, heptamethine oxonol colorant, pentamethine oxonol colorant, phthalocyanine colorant, naphthalocyanine colorant and the like is advantageous.

When the oscillation wavelength of the laser light source is in the vicinity of 660 nm, selection of a colorant from trimethine cyanine colorant, pentamethine oxonol colorant, azo colorant, azo metal complex colorant, pyrromethene complex colorant and the like is advantageous.

When the oscillation wavelength of the laser light source is in the vicinity of 405 nm, selection of a colorant from monomethine cyanine colorant, monomethine oxonol colorant, zeromethine merocyanine colorant, phthalocyanine colorant, azo colorant, azo metal complex colorant, porphyrin colorant, allylidene colorant, complex colorant, coumarin colorant, azole derivative, triazine derivative, benzotriazole derivative, 1-aminobutadiene derivative, quinophthalone-based colorant and the like is advantageous.

Preferred examples of compounds suitable for the organic layer, when the oscillation wavelength of the laser light source is in the vicinity of 405 nm, will be mentioned below. The compounds represented by Structural Formulae III-1 to III-14 below are preferred examples when the oscillation wavelength of the laser light source is in the vicinity of 405 nm. Meanwhile, preferred examples of compounds suitable for the organic layer, when the oscillation wavelength of the laser light source is in the vicinity of 780 nm or 660 nm, include the compounds mentioned in the paragraphs [0024] to [0028] of JP-A No. 2008-252056. In the present invention, use of any of these compounds is not compulsory.

<Examples of Compounds when Oscillation Wavelength of Laser Light Source is in the Vicinity of 405 nm>

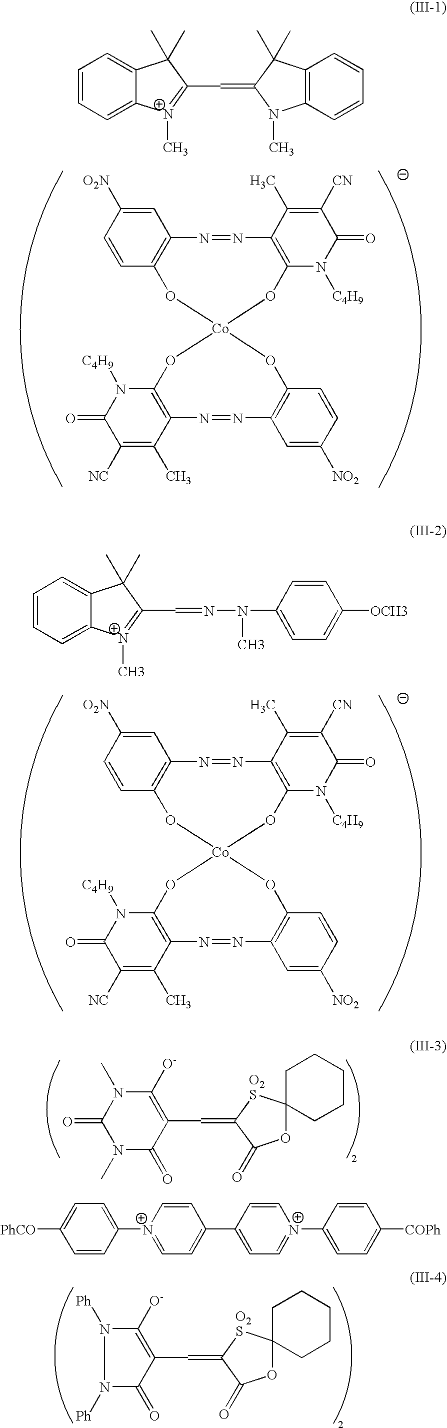

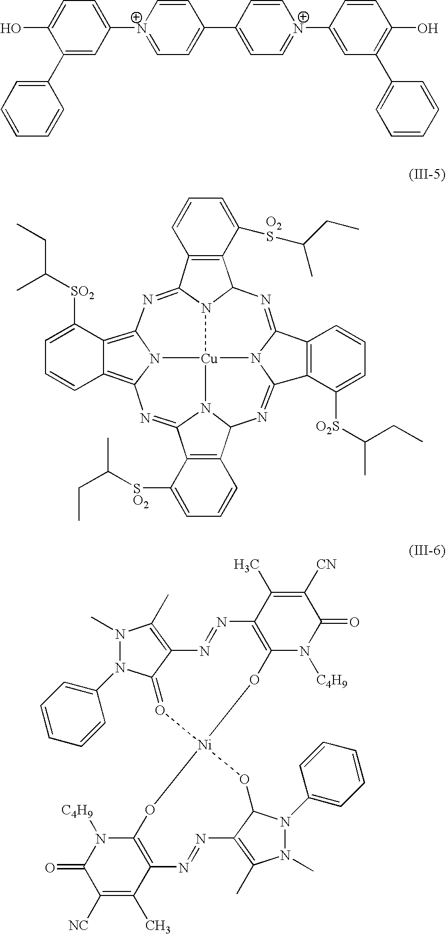

<Examples of Compounds when Oscillation Wavelength of Laser Light Source is in the Vicinity of 405 nm>

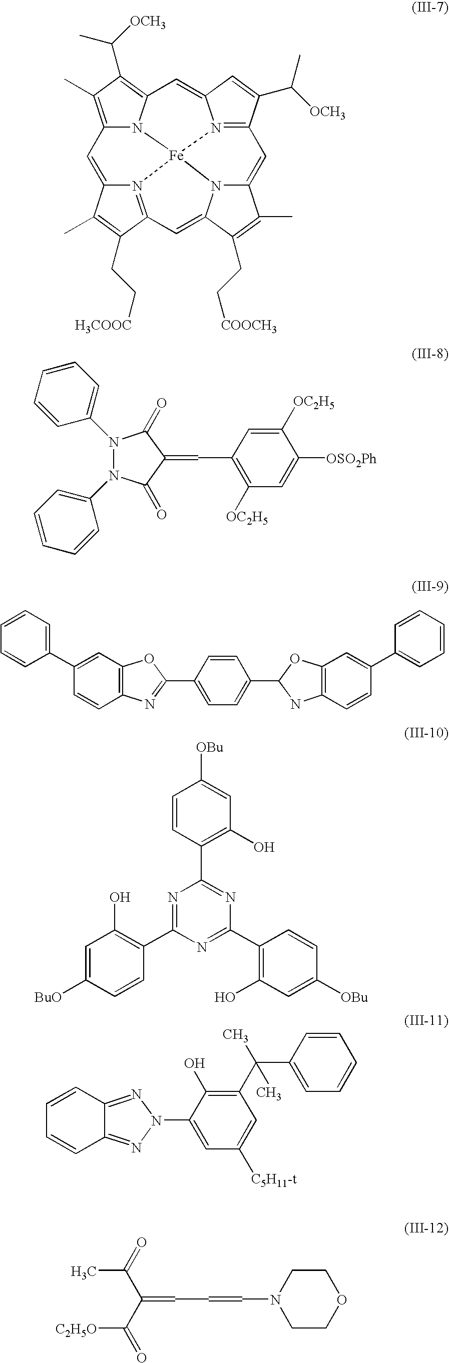

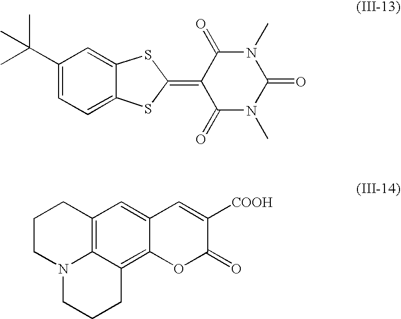

Moreover, colorants disclosed in JP-A Nos. 04-74690, 08-31127174, 11-3153758, 11-31334204, 11-31334205, 11-31334206, 11-334207, 2000-43423, 2000-108513, and 2000-158818 are suitably used.

A coating solution for such a colorant-containing organic layer is prepared by dissolving a colorant in a solvent along with a bonding agent, etc. The organic layer can be formed by applying this coating solution onto the base so as to form a coating film and then drying it. At that time, the temperature of the surface of the base onto which the coating solution is applied is preferably in the range of 10° C. to 40° C. The lower limit value of the temperature is preferably 15° C. or higher, more preferably 20° C. or higher, particularly preferably 23° C. or higher. The upper limit value of the temperature is preferably 35° C. or lower, more preferably 30° C. or lower, particularly preferably 27° C. or lower. When the temperature of the surface is in the above-mentioned range, it is possible to prevent the occurrence of uneven application of the coating solution or application trouble and make the coating film have a uniform thickness. Note that the upper limit value and the lower limit value may be arbitrarily and independently set.

Here, the organic layer may have a single-layer structure or a multilayer structure; in the case where it has a multilayer structure, it is formed by carrying out a coating process two or more times.

As for the concentration of the colorant in the coating solution, it is desirable that the colorant be dissolved in the solvent so as to occupy 0.3% by mass to 30% by mass, more desirably 1% by mass to 20% by mass, of the solvent. It is particularly desirable that the colorant be dissolved in tetrafluoropropanol so as to occupy 1% by mass to 20% by mass of 2,2,3,3-tetrafluoropropanol.

The solvent used in the coating liquid is suitably selected depending on the intended purpose without any restriction. Examples thereof include: esters such as butyl acetate, ethyl lactate, and cellosolve acetate; ketones such as methylethyl ketone, cyclohexanone, and methylisobutyl ketone; chlorinated hydrocarbons such as dichloromethane, 1,2-dichloroethane, and chloroform; amides such as dimethylformamide; hydrocarbons such as methyl cyclohexane; ethers such as tetrahydrofuran, ethyl ether, and dioxane; alcohols such as ethanol, n-propanol, isopropanol, n-butanol, and diacetone alcohol; fluoro solvents such as 2,2,3,3-tetrafluoropropanol; and glycol ethers such as ethylene glycol monomethyl ether, ethylene glycol monoethyl ether, and propylene glycol monomethyl ether. Among them, butyl acetate, ethyl lactate, cellosolve acetate, methylethyl ketone, isopropanol, and 2,2,3,3-tetrafluoropropanol are particularly preferable.

Under the consideration of the solubility of the colorant for use, the solvents may be used independently, or in combination. To the coating liquid, various additives, such as an antioxidant, a UV absorbing agent, a plasticizer, and a lubricant, may be added depending on the intended purpose.

The method for the application of the coating solution is suitably selected depending on the intended purpose without any restriction. Examples thereof include spraying, spin coating, dipping, roll coating, blade coating, doctor roll method, doctor blade method and screen printing. Among these, employment of spin coating is preferable in terms of productivity and facilitation of control of the film thickness.

It is desirable that the colorant be dissolved in the solvent so as to occupy 0.3% by mass to 30% by mass, more desirably 1% by mass to 20% by mass, of the solvent because, if so, the organic layer can be advantageously formed by spin coating.

The thermolysis temperature of the colorant is preferably 150° C. to 500° C., more preferably 200° C. to 400° C.

The temperature of the coating solution when applied is preferably 23° C. to 50° C., more preferably 24° C. to 40° C., yet more preferably 25° C. to 30° C.

In the case where the coating solution contains a bonding agent, the bonding agent is suitably selected depending on the intended purpose without any restriction. Examples thereof include natural organic polymeric substances such as gelatin, cellulose derivatives, dextran, rosin and rubber; hydrocarbon-based resins such as polyethylene, polypropylene, polystyrene and polyisobutylene; vinyl-based resins such as polyvinyl chloride, polyvinylidene chloride and polyvinyl chloride-polyvinyl acetate copolymer; acrylic resins such as polymethyl acrylate and polymethyl methacrylate; synthetic organic polymers, for example initial condensates of thermosetting resins such as polyvinyl alcohol, chlorinated polyethylene, epoxy resins, butyral reins, rubber derivatives and phenol-formaldehyde resins.

As for the amount of the bonding agent when used as a material for the organic layer, it is generally desirable that the mass of the bonding agent be 0.01 times to 50 times the mass of the colorant, and more desirable that the mass of the bonding agent be 0.1 times to 5 times the mass of the colorant.

A discoloration preventing agent selected from a variety of discoloration preventing agents may be contained in the organic layer to improve the light resistance of the organic layer.

As the discoloration preventing agent, a singlet oxygen quencher is generally used. The singlet oxygen quencher may be selected from quenchers mentioned in already known publications such as patent specifications.

Specific examples thereof include those mentioned in JP-A Nos. 58-175693, 59-81194, 60-18387, 60-19586, 60-19587, 60-35054, 60-36190, 60-36191, 60-44554, 60-44555, 60-44389, 60-44390, 60-54892, 60-47069, 63-209995 and 04-25492, Japanese Patent Application Publication (JP-B) Nos. 01-38680 and 06-26028, German Patent No. 350399, and p. 1141 of the October, 1992 issue of Journal of the Chemical Society of Japan.

The amount of the discoloration preventing agent such as a singlet oxygen quencher is preferably 0.1% by mass to 50% by mass, more preferably 0.5% by mass to 45% by mass, yet more preferably 3% by mass to 40% by mass, particularly preferably 5% by mass to 25% by mass, with respect to the amount of the colorant.

Although the foregoing has described a solvent applying method for formation of the organic layer, it should be noted that the organic layer can also be formed by a deposition method such as vacuum deposition, sputtering or CVD.

A colorant which is higher in absorptance at the wavelength of laser light used in the after-mentioned formation of concave portions than at any other wavelength is used as the colorant.

The absorption peak wavelength of the colorant is not necessarily in the wavelength region of visible light but may be in the ultraviolet or infrared wavelength region.

The absorption peak wavelength of the colorant λa and the wavelength λw of laser light for forming concave portions preferably satisfy the relationship: λa<λw. If this relationship is satisfied, the amount of light absorbed by the colorant is appropriate, thereby enhancing recording efficiency, and an exquisite convex-concave shape may be able to be formed. Also, the relationship λw<λc is preferably satisfied. This is because λw should be the wavelength at which the colorant absorbs light, so that when the central wavelength λc of light emitted by a light emitting device is longer than the wavelength λw, the light emitted by the light emitting device is not absorbed into the colorant and thus there is an increase in transmittance, thereby improving luminous efficacy.

From the foregoing viewpoint, the relationship λa<λw<λc will be most desirable.

The wavelength λw of the laser light for forming the concave portions should be such a wavelength as makes it possible to obtain great laser power; for example, in the case where a colorant is used in the organic layer, the wavelength λw is preferably 1,000 nm or less, e.g. 193 nm, 210 nm, 266 nm, 365 nm, 405 nm, 488 nm, 532 nm, 633 nm, 650 nm, 680 nm, 780 nm or 830 nm.

As for the type of the laser light, the laser light may be any of a gas laser, a solid-state laser, a semiconductor laser and the like. It should, however, be noted that employment of a solid-state laser or a semiconductor laser is preferable in view of simplification of an optical system. The laser light may be continuous light or pulsed light, and it is preferable to employ laser light with freely alterable luminous intervals. For example, it is preferable to employ a semiconductor laser. In the case where the laser cannot be directly subjected to on-off modulation, it is preferable to modulate the laser using an external modulation device.

The laser power is preferably high in view of increasing the processing speed. It should, however, be noted that as the laser power is increased, the scanning speed (speed at which the organic layer is scanned with the laser light) has to be increased as well. Therefore, in view of the upper limit value of the scanning speed, the upper limit value of the laser power is preferably 100 W, more preferably 10 W, yet more preferably 5 W, particularly preferably 1 W. The lower limit value of the laser power is preferably 0.1 mW, more preferably 0.5 mW, yet more preferably 1 mW.

Further, it is desirable that the laser light be superior in oscillation wavelength width and coherency and can be focused to a spot size equivalent to its wavelength. As for light pulse irradiation conditions for appropriately forming the concave portions, it is desirable to employ such a strategy as used for optical disks. Specifically, it is desirable to employ such conditions in relation to the recording speed and the crest value and pulse width of applied laser light as used for optical disks.

It is desirable that the thickness of the organic layer correspond to the depth of the concave portions 15, which will be mentioned later.

The thickness of the organic layer can, for example, be set in the range of 1 nm to 10,000 nm. The lower limit value of the thickness is preferably 10 nm or more, more preferably 30 nm or more. When the organic layer is too thin, concave portions 15 which are shallow are formed, so that optical effects may not be obtained. The upper limit value of the thickness is preferably 1,000 nm or less, more preferably 500 nm or less. When the organic layer is too thick, great laser power is required, formation of deep holes may be difficult, and further, the processing speed may decrease.

Also, the thickness t of the organic layer and the diameter d of a concave portion preferably satisfy the following relationship.

Regarding the upper limit value of the thickness t of the organic layer, the relationship t<10d is preferably satisfied, more preferably t<5d, yet more preferably t<3d. Regarding the lower limit value of the thickness t of the organic layer, the relationship t>d/100 is preferably satisfied, more preferably t>d/10, yet more preferably t>d/5. The reasons why the upper and lower limit values of the thickness t of the organic layer are set in relation to the diameter d of the concave portion are similar to the above-mentioned reasons.

At the time of formation of the organic layer, the organic layer can be formed by dissolving or dispersing a colorant in a certain solvent so as to prepare a coating solution, and then applying this coating solution onto the surface of the base by a coating method such as spin coating, dip coating or extrusion coating.

A plurality of concave portions is periodically formed in the organic layer. These concave portions are formed by irradiating the organic layer with condensed light so as to deform the irradiated portions (which includes deformation by loss).

The principle of the formation of the concave portions is as follows.

When the organic layer is irradiated with laser light having a wavelength at which a material absorbs light (laser light having such a wavelength as to be absorbed by the material), the laser light is absorbed by the organic layer, this absorbed light is converted to heat, and the irradiated portions increase in temperature. Thus, the organic layer undergoes chemical and/or physical change(s) such as softening, liquefaction, vaporization, sublimation, decomposition, etc. As the material having undergone such change(s) moves and/or disappears, concave portions are formed.

The formation method of the concave portions is suitably selected depending on the intended purpose without any restriction. For example, a pit forming method known in relation to write-once optical disks, recordable optical disks, etc. may be used. Specifically, a known technique for running OPC may, for example, be used which involves detecting the intensity of reflected laser light, which changes according to the pit size, correcting the output of the laser light such that the intensity of the reflected laser light becomes constant, and thusly forming uniform pits (refer to Japanese Patent (JP-B) No. 3096239).

The above-mentioned vaporization, sublimation or decomposition of the organic layer preferably takes place at a great change rate and precipitously.

Specifically, the mass reduction rate at the time of the vaporization, sublimation or decomposition of the colorant, measured using a differential thermal balance (TG-DTA), is preferably 5% or more, more preferably 10% or more, yet more preferably 20% or more. Also, the slope of the mass reduction (i.e. the mass reduction rate with respect to an increase in temperature by 1° C.) at the time of the vaporization, sublimation or decomposition of the colorant, measured using a differential thermal balance (TG-DTA), is preferably 0.1%/° C. or more, more preferably 0.2%/° C. or more, yet more preferably 0.4%/° C. or more.

The upper limit value of the transition temperature in relation to the chemical and/or physical change(s) such as softening, liquefaction, vaporization, sublimation, decomposition, etc. is preferably 2,000° C. or lower, more preferably 1,000° C. or lower, yet more preferably 500° C. or lower. When the transition temperature is too high, great laser power may be required. The lower limit value of the transition temperature is preferably 50° C. or higher, more preferably 100° C. or higher, yet more preferably 150° C. or higher. When the transition temperature is too low, the temperature gradient between the target portions and surrounding portions is low, so that the shape of hole edges may not be clear.

FIG. 5A is a drawing showing an example of an organic layer as seen in a planar view, FIG. 5B is a drawing showing another example of an organic layer as seen in a planar view, and FIG. 5C is a cross-sectional view showing a base and an organic layer. As shown in FIG. 5A, concave portions 15 formed in the shape of dots which are arranged in the form of a lattice may be employed. Meanwhile, as shown in FIG. 5B, concave portions 15 may be formed as long thin grooves which extend with spaces in between. Further, although not shown, concave portions 15 may be formed as continuous grooves.

The pitch P of the concave portions 15 is 0.01 times to 100 times the central wavelength λc of light emitted by an LED device 10 as a luminous member.

The pitch P of the concave portions 15 is preferably 0.05 times to 20 times, more preferably 0.1 times to 5 times, yet more preferably 0.5 times to 2 times, the central wavelength λc. Specifically, the lower limit value of the pitch P is preferably 0.01 times or more, more preferably 0.05 times or more, yet more preferably 0.1 times or more, particularly preferably 0.2 times or more, the central wavelength λc. The upper limit value of the pitch P is preferably 100 times or less, more preferably 50 times or less, yet more preferably 10 times or less, particularly preferably 5 times or less, the central wavelength λc.

The diameter or groove width of each concave portion 15 is preferably 0.005 times to 25 times, more preferably 0.025 times to 10 times, yet more preferably 0.05 times to 2.5 times, particularly preferably 0.25 times to 2 times, the central wavelength λc.

The diameter or groove width herein mentioned is the diameter or width of each concave portion 15 measured at the midpoint of the depth of the concave portion 15, in other words the half-value width.

The diameter or groove width of each concave portion 15 may be suitably set in the above-mentioned range; it is preferable to set the diameter or groove width according to the pitch P such that the refractive index gradually decreases in a macroscopic manner in proportion to the distance from the emitting surface 18. Specifically, when the pitch P is large, it is preferable to make the diameter or groove width of the concave portion 15 large as well; whereas when the pitch P is small, it is preferable to make the diameter or groove width of the concave portion 15 small as well. From the foregoing viewpoint, it is desirable that the diameter or groove width be approximately half the pitch P, preferably 20% to 80%, more preferably 30% to 70%, yet more preferably 40% to 60%, of the pitch P.

The depth of each concave portion 15 is preferably 0.01 times to 20 times, more preferably 0.05 times to 10 times, yet more preferably 0.1 times to 5 times, particularly preferably 0.2 times to 2 times, the central wavelength λc.

### —Convex-Concave Forming Method (2) (Imprint Method)—

As the imprinting method, a thermal nanoimprinting method or optical nanoimprinting method may be employed.

In the nanoimprinting method, a plurality of convex portions of an imprint mold is pressed against an imprint layer formed on the surface of a base. Here, the temperature of the system is kept in the vicinity of the glass transition temperature (Tg) of the imprint layer, and the temperature of the imprint layer becomes lower than the glass transition temperature of a thermoplastic resin contained in the imprint layer after the transfer of the pattern, thereby curing the thermoplastic resin. When the imprint mold is separated from the imprint layer, a convex-concave pattern is formed at the imprint layer.

In the optical nanoimprinting method, a resist convex-concave pattern is formed using an imprint mold which transmits light and which is made of a material (for example, quartz (SiO₂), an organic resin (PET, PEN, polycarbonate, low-melting-point fluorine resin, etc.) or the like) having such strength as can function as an imprint mold.

Subsequently, an imprint layer formed of an imprint composition containing at least a photocurable resin is irradiated with an ultraviolet ray or the like so as to harden the pattern transferred thereto. Here, note that the pattern may be hardened by ultraviolet irradiation after the mold is released from a base with the imprint layer, which follows the patterning.

The imprint mold is preferably the one which is formed by performing etching using, as a mask, an organic layer in which the convex-concave portion has been formed by applying the condensed light to the organic layer capable of changing the shape thereof with heat.

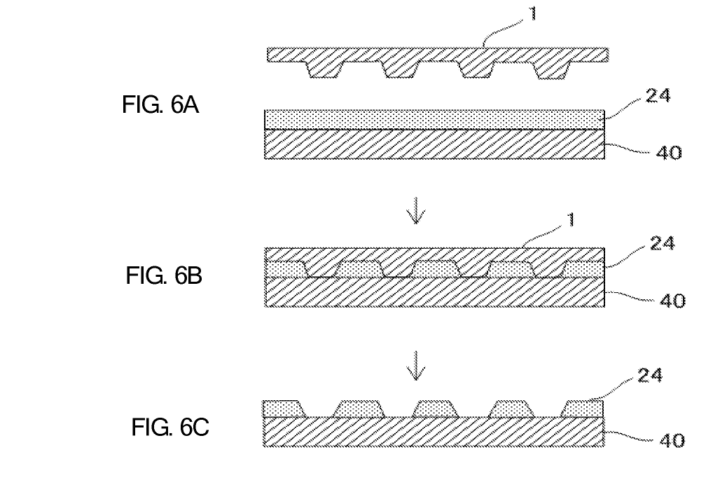

FIGS. 6A to 6C are process drawings together showing a method of forming a convex-concave pattern by imprinting.

As shown in FIG. 6A, an imprint mold 1 with a convex-concave pattern formed on its surface is pressed against an imprint layer 24 formed on a base 40, which is made of aluminum, glass, silicon or quartz, by applying an imprint resist solution containing polymethyl methacrylate (PMMA) or the like onto the base 40.

Next, as shown in FIG. 6B, when the imprint mold 1 is being pressed against the imprint layer 24, the temperature of the system is kept in the vicinity of the glass transition temperature (Tg) of the imprint resist solution, and the temperature of the imprint layer 24 becomes lower than the glass transition temperature of the imprint resist solution after the transfer of the pattern, thereby curing the imprint resist solution. If necessary, the imprint resist solution may be cured by heating or UV irradiation. Thus, the convex-concave pattern formed on the imprint mold 1 is transferred to the imprint layer 24.

Subsequently, as shown in FIG. 6C, when the imprint mold 1 is separated from the imprint layer 24, a convex-concave pattern is formed in the imprint layer 24.

### <Auxiliary Electrode Layer Forming Step>

The auxiliary electrode layer forming step is forming an auxiliary electrode layer formed of a conductive material at least on slant faces of the convex-concave portion.

It is preferred that the auxiliary electrode layer be formed at least on slant face(s) of the convex-concave portion. The formation method thereof is suitably selected depending on the intended purpose without any restriction. For example, the auxiliary electrode layer can be formed only on the areas of the convex portions facing to the deposition source by vacuum depositing a conductive material to the convex-concave portion from the upper oblique position relative to the convex-concave portion.

The forming method of the auxiliary electrode layer is suitably selected depending on the intended purpose without any restriction, provided that it can selectively form an auxiliary electrode layer at least on the slant faces on the convex-concave portion. Examples thereof include vacuum deposition, sputtering, CVD, plating, deposition in a solution, and spraying. Among them, the vacuum deposition, low-pressure sputtering, and spraying are preferable, and the vacuum deposition is particularly preferable.

Examples of the vacuum deposition include electron-beam evaporation, and ion plating.

Examples of the sputtering preferably include a low-pressure deposition and a high-pressure deposition. The pressure of the deposition surface is preferably 0.1 Pa or less, more preferably 0.01 Pa or less, yet more preferably 0.001 Pa or less. The low-pressure deposition can be realized by decreasing the pressure of a deposition surface area only or by a method such as ion beam sputtering.

In the case of high-pressure deposition, preferred methods include a method of increasing the pressure at the time of deposition and selectively depositing fine particles on convex portions. The pressure of the deposition surface is preferably 0.5 Pa or more, more preferably 5 Pa or more.

### —Vacuum Deposition—

The vacuum deposition is preferably performed at an angle (deposition angle) of 1 degree to 80 degrees with respect to the vertical direction of the base, with the side of the base where the convex-concave portion has been formed facing to the direction from which the vacuum deposition is performed.

The lower limit of the angle for performing the vacuum deposition is preferably 1 degree or larger, more preferably 5 degrees or larger, yet more preferably 10 degrees or higher. When the angle is too small, the deposition efficiency may be decreased.

The upper limit of the deposition angle is preferably 80 degrees or smaller, more preferably 70 degrees or smaller, yet more preferably 60 degrees or smaller, particularly preferably 50 degrees or smaller. When the deposition angle is larger than 80 degrees, the deposition material is hardly deposited on a subjective surface, decreasing the deposition efficiency, even with the adhesive force of the deposited matter being decreased.

Note that, in the case where the depth of the convex portion is larger than the thickness of the vacuum-deposited matter and the slope of the convex portion is steep, the angle is not necessarily 90 degrees (i.e., the deposition angle is not necessarily be set).

With respect to the pressure for the vacuum deposition, the upper limit thereof is preferably 1×10⁻³ Torr, more preferably 5×10⁻⁴ Torr, yet more preferably 1×10⁻⁴ Torr. The lower limit thereof is preferably 1×10⁻⁸ Torr, more preferably 5×10⁻⁷ Torr, yet more preferably 1×10⁻⁶ Torr. With respect to the speed of the deposition, the upper limit thereof is preferably 100 nm/s, more preferably 20 nm/s, yet more preferably 5 nm/s. The lower limit thereof is preferably 0.001 nm/s, more preferably 0.01 nm/s, yet more preferably 0.1 nm/s.

The conductive material for use in the vacuum deposition is suitably selected depending on the intended purpose without any restriction, provided that it can be used for the vacuum deposition. Suitable examples thereof include various metals such as Ag, Ni, Cu, Al, Mo, Co, Cr, Ta, Pd, Pt, and Au, and alloys thereof.

The thickness of the auxiliary electrode layer is suitably selected depending on the intended purpose without any restriction. For example, it is preferably 10 nm to 50,000 nm, more preferably 50 nm to 5,000 nm, yet more preferably 100 nm to 1,000 nm.

### <Transparent Conductive Layer Forming Step>

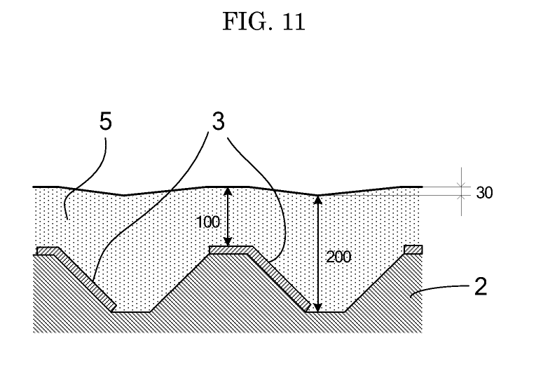

The transparent conductive layer forming step is forming a transparent conductive layer on surfaces of the convex-concave portion and the auxiliary electrode layer. Specifically, as shown in FIG. 11, a transparent conductive layer 5 is formed on a surface of the convex-concave portion where the auxiliary electrode layer is not formed, and a surface of the auxiliary electrode layer 3 formed on the convex-concave portion.

The transparent conductive layer is suitably selected depending on the intended purpose without any restriction. For example, it can be formed by depositing at least one selected from a transparent conductive polymer (e.g., PEDOT/PSS, polyaniline, polypyrrole, polythiophene, and polyisothianaphthene), a conductive metal (e.g., metal oxide, metal particles, metal nanorods, and metal nanowires), conductive inorganic particles (e.g. carbon nanotubes), and a water-soluble organic salt by coating or printing. Among them, the use of the conductive polymer is particularly preferable.

These coating solutions may be blended into another non-conductive polymer or latex for improving coating ability or adjusting the properties of the coated film. Moreover, the transparent conductive layer may have a laminate structure in which a thin silver film is sandwiched with a pair of layers having high refractive indexes. The details of the transparent conductive materials are disclosed, for example, in Current Situation and Feature of Electromagnetic Wave Shielding Material, published by Toray Research Center Inc., and JP-A No. 09-147639.

The method for coating or printing is suitably selected depending on the intended purpose without any restriction. Examples thereof include: coating by a coater, such as a slide coater, a slot die coater, a curtain coater, a roll coater, a bar coater, and a gravure coater; and screen printing.

As for the conductive polymer, those having high light permeability and high conductivity are preferable, and electron-conductive polymers such as polythiophenes, polypyrroles, and polyaniline are preferable.

The electron-conductive polymers are known polymers in the art, such as polyacetylene, polypyrrole, polyaniline, and polythiophene. The details thereof are disclosed, for example, in “Advances in Synthetic Metals”, ed. P. Bernier, S. Lefrant, and G. Bidan, Elsevier, 1999; “Intrinsically Conducting Polymers: An Emerging Technology”, Kluwer (1993); “Conducting Polymer Fundamentals and Applications, A Practical Approach”, P. Chandrasekhar, Kluwer, 1999; and “Handbook of Organic Conducting Molecules and Polymers”, Ed. Walwa, Vol. 1-4, Marcel Dekker Inc. (1997). These electron-conductive polymers may be used independently, or in combination as a polymer blend.

The thickness of the transparent conductive layer (excluding the convex portion) is suitably selected depending on the intended purpose without any restriction. It is preferably 10 nm to 50,000 nm, more preferably 50 nm to 5,000 nm, yet more preferably 100 nm to 1,000 nm.

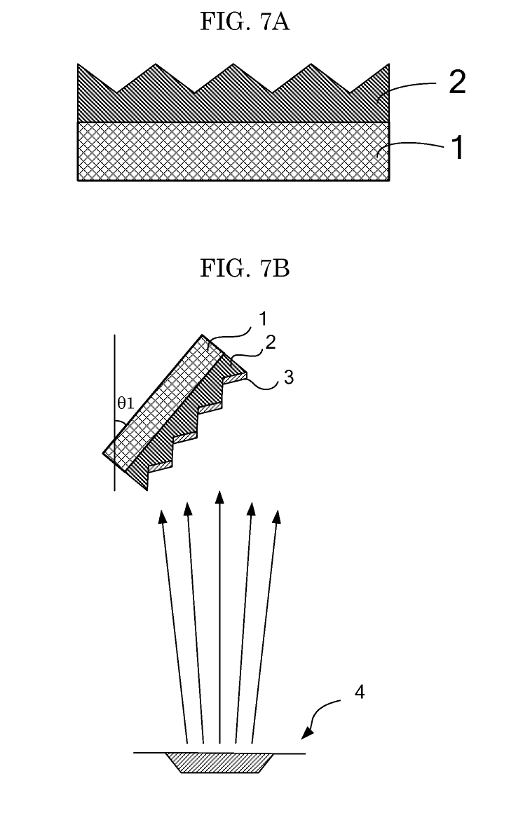

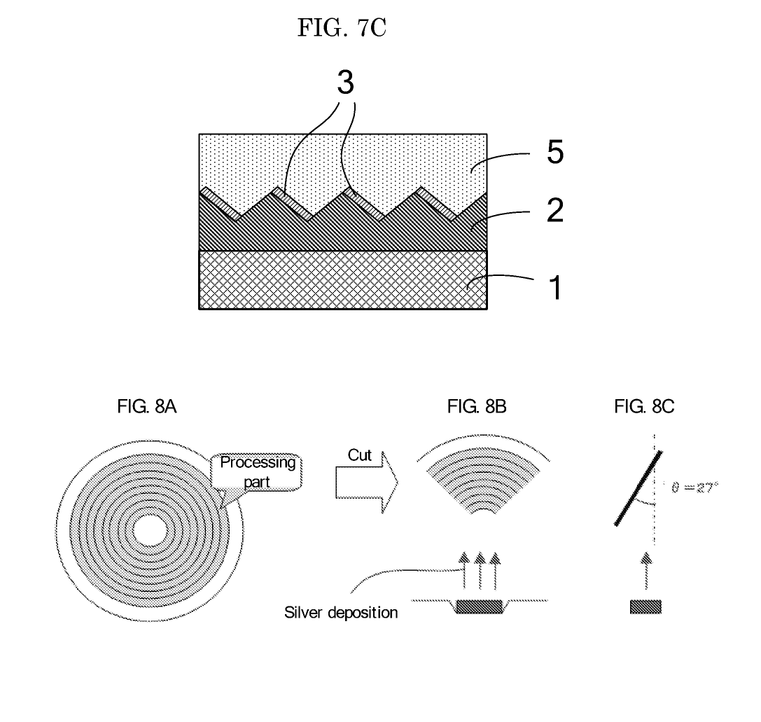

An embodiment of the method for producing a transparent conductor of the present invention will be explained with reference to FIGS. 7A to 7C, hereinafter.

FIG. 7A is a diagram showing the convex-concave portion forming step in which a convex-concave portion is formed on a surface of a base 1 such that a plurality of convex portions are aligned based on the surface of the base 1. The formation method of the convex-concave portion is suitably selected depending on the intended purpose without any restriction, and suitably examples thereof include a method in which the convex-concave portion is formed by exposing an organic layer 2 capable of changing the shape thereof in a head mode to condensed light, and a nanoimprint method.

FIG. 7B is a diagram showing the auxiliary electrode layer forming step in which an auxiliary electrode layer 3 formed of a conductive material is formed at least on slant faces of the convex-concave portion. The auxiliary electrode layer can be formed on the slant faces of the convex-concave portion by placing the surface of the base 1 where the convex-concave portion has been formed towards the vacuum deposition device 4, and obliquely performing vacuum deposition at an angle θ1 of 1 degree to 80 degrees with respect to the vertical direction of the base.

FIG. 7C is a diagram showing the transparent conductive layer forming step, in which a transparent conductive layer is formed on surfaces of the convex-concave portion and the auxiliary electrode layer. The transparent conductive layer 5 is applied and formed on the surfaces of the convex-concave portion and the auxiliary electrode layer 3, to thereby obtain a transparent conductor.

According to the method for producing a transparent conductor of the present invention, a transparent conductive layer is formed on a surface of the auxiliary electrode layer, which has been formed by oblique vacuum deposition in the auxiliary electrode layer forming step, and a surface of the convex-concave portion by a coating method using a conductive polymer solution, to thereby form the transparent conductive layer having a flat surface.

Moreover, the auxiliary electrode layer formed on the convex-concave portion has a three-dimensional structure such that it is thick in the light transmitting direction, but is narrow in the opening direction. As a result, the transparency and conductivity of the transparent conductor can be improved compared to those of the conventional conductor.

### —Use—

The transparent conductor of the present invention can be widely applied, such as a use as a transparent electrode for a liquid crystal display, a plasma display, an electroluminescence display, an electrochromic display, a solar battery, and a touch panel, a use as an electronic paper, and a use as a shielding material for electromagnetic waves.

### EXAMPLES

Hereinafter, examples of the present invention will be explained, but these examples shall not be construed as limiting the scope of the present invention.

### Example 1

A silicon disc substrate having a diameter of 4 inches was used. Onto the silicon substrate, a solution prepared by dissolving 15 mg of an oxonol organic material (a heat mode material 1) expressed by the following structural formula in 1 mL of 2,2,3,3-tetrafluoro-1-propanol was applied by means of a spin coater at the revolution number of 300 rpm, followed by at the revolution number of 1,000 rpm, then dried to thereby form an organic layer having a thickness of 70 nm.

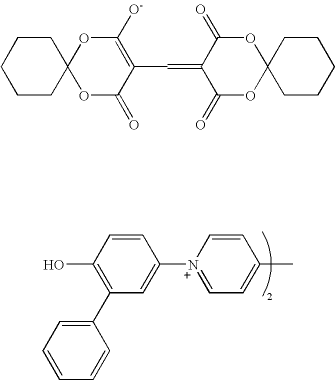

Next, laser light was applied to the organic layer on the silicon substrate by means of NEO 1000 (manufactured by Pulstec Industrial Co., Ltd.) at the conditions of 5 m/s and 4 mW, and at the pitch of 500 nm in the circumferential direction. As a result, the substrate having the organic layer which had concave portions formed in the surface thereof was obtained.

The silicon substrate was then dry etched using the organic layer to which the convex-concave portion had been formed as a mask, to thereby form concave portions each having a depth of 200 nm on the silicon substrate. The remained organic layer on the silicon substrate was dissolved and removed by 2,2,3,3-tetrafluoro-1-propanol. Note that, the conditions for the dry etching were such that a reactive ion etching (RIE) was performed using SF6 gas, at an output of 150 W for 40 seconds. In the manner mentioned above, an imprint mold was prepared.

Next, a photocurable resin (PAK01, manufactured by Toyo Gosei Co., Ltd.) was applied onto a polycarbonate substrate having a thickness of 80 μm to thereby form an imprint layer having a thickness of 10 μm.

The previously prepared imprint mold was pressed against the imprint layer on the polycarbonate substrate, and in this condition the imprint layer was cured with UV light so as to transfer the convex-concave pattern of the imprint mold to the imprint layer. Then, the imprint mold was released from the imprint layer to thereby prepare a convex-concave portion on the polycarbonate substrate (Convex-concave portion forming step, see FIG. 8A).

The convex-concave portion formed on the polycarbonate substrate was observed under a scanning electron microscope (SEM), and it was found that in FIG. 1, a pitch P was 500 nm, a flat width a of the convex portion was 50 nm, a width b of the slant portion was 150 nm, a flat width c of the bottom part was 150 nm, a height d of the convex portion was 150 nm, and a slant angle θ of the slant portion was 45 degrees.

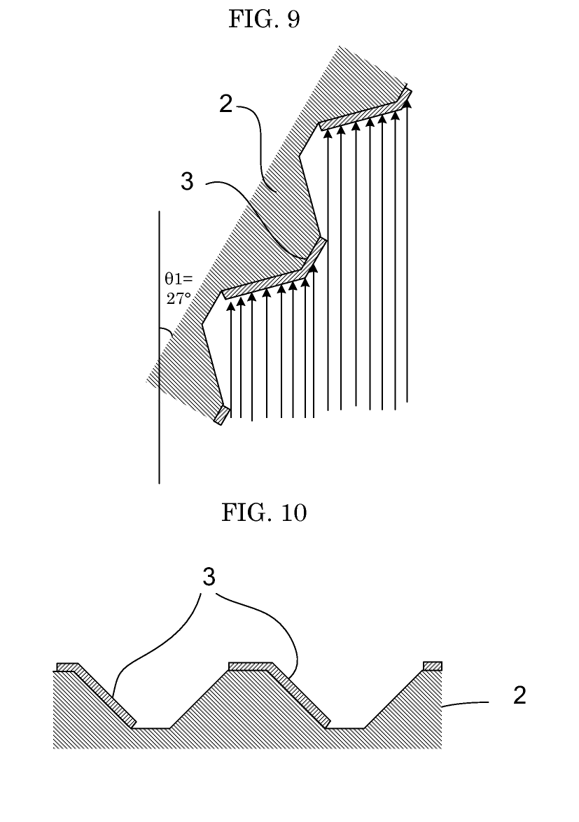

Next, as shown in FIG. 8B, the polycarbonate substrate to which the convex-concave portion had been formed was cut into ¼, and as shown in FIG. 8C, the polycarbonate substrate to whose surface the convex-concave portion had been formed was placed so that the side of the polycarbonate substrate where the concave-convex portion was present faces the side from where a vacuum deposition was applied, and then the vacuum deposition was performed using silver as a conductive material at an angle θ1 of 27 degrees with respect to the vertical direction of the substrate. As shown in FIG. 9, auxiliary electrode layers each having a thickness of 20 nm were formed at least on the slant portions of the convex-concave portion (Auxiliary electrode layer forming step, see FIG. 10).

The auxiliary electrode layer on the slant face had an angle of 45 degrees with respect to the vertical direction of the substrate.

Thereafter, onto the surfaces of the convex-concave portion and the auxiliary electrode layers, a conductive polymer solution (Baytron P, manufactured by H. C. Starck) was spin-coated at 1,000 rpm, and dried, to thereby form a transparent conductive layer having a thickness of 100 nm to 200 nm (Transparent conductive layer forming step, see FIG. 11). In the manner mentioned above, a transparent conductor of Example 1 was prepared.

### Example 2

A silicon disc substrate having a diameter of 4 inches was used. Onto the silicon substrate, a solution prepared by dissolving 15 mg of an oxonol organic material (a heat mode material 2) expressed by the following structural formula in 1 mL of 2,2,3,3-tetrafluoro-1-propanol was applied by means of a spin coater at the revolution number of 300 rpm, followed by at the revolution number of 1,000 rpm, then dried to thereby form an organic layer having a thickness of 70 nm.

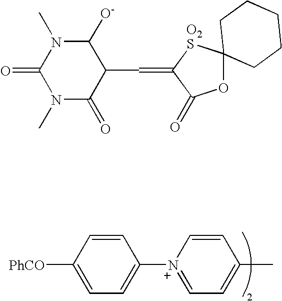

Next, laser light was applied to the organic layer on the silicon substrate by means of NEO 1000 (manufactured by Pulstec Industrial Co., Ltd.) at the conditions of 5 m/s and 6 mW, and at the pitch of 600 nm in the circumferential direction. As a result, the substrate having the organic layer which had concave portions formed in the surface thereof was obtained.

The silicon substrate was then dry etched using the organic layer to which the convex-concave portion had been formed as a mask, to thereby form concave portions each having a depth of 200 nm on the silicon substrate. The remained organic layer on the silicon substrate was dissolved and removed by 2,2,3,3-tetrafluoro-1-propanol. Note that, the conditions for the dry etching were such that a reactive ion etching (RIE) was performed using SF6 gas, at an output of 150 W for 40 seconds. In the manner mentioned above, an imprint mold was prepared.

Next, a photocurable resin (PAK01, manufactured by Toyo Gosei Co., Ltd.) was applied onto a polycarbonate substrate having a thickness of 80 μm to thereby form an imprint layer having a thickness of 10 μm.

The previously prepared imprint mold was pressed against the imprint layer on the polycarbonate substrate, and in this condition the imprint layer was cured with UV light so as to transfer the convex-concave pattern of the imprint mold to the imprint layer. Then, the imprint mold was released from the imprint layer to thereby prepare a convex-concave portion on the polycarbonate substrate (Convex-concave portion forming step).

The convex-concave portion formed on the polycarbonate substrate was observed under a scanning electron microscope (SEM), and it was found that in FIG. 1, a pitch P was 600 nm, a flat width a of the convex portion was 100 nm, a width b of the slant portion was 150 nm, a flat width c of the bottom part was 200 nm, a height d of the convex portion was 150 nm, and a slant angle θ of the slant portion was 45 degrees.

Next, the polycarbonate substrate to which the convex-concave portion had been formed was cut into ¼, and the polycarbonate substrate to whose surface the convex-concave portion had been formed was placed so that the side of the polycarbonate substrate where the concave-convex portion was present faces the side from where a vacuum deposition was applied, and then the vacuum deposition was performed using silver as a conductive material at an angle θ1 of 23 degrees with respect to the vertical direction of the substrate. Auxiliary electrode layers each having a thickness of 20 nm were formed at least on the slant portions of the convex-concave portion (Auxiliary electrode layer forming step).

The auxiliary electrode layer on the slant face had an angle of 45 degrees with respect to the vertical direction of the substrate.

Thereafter, onto the surfaces of the convex-concave portion and the auxiliary electrode layers, a conductive polymer solution (Baytron P, manufactured by H. C. Starck) was spin-coated at 1,000 rpm, and dried, to thereby form a transparent conductive layer having a thickness of 100 nm to 200 nm (Transparent conductive layer forming step). In the manner mentioned above, a transparent conductor of Example 2 was prepared.

### Example 3

A silicon disc substrate having a diameter of 4 inches was used. Onto the silicon substrate, a solution prepared by dissolving 15 mg of a phthalocyanine organic material [ZnPc(α-SO₂Bu-sec)₄] (a heat mode material 3) in 1 mL of acetone was applied by means of a spin coater at the revolution number of 300 rpm, followed by at the revolution number of 1,000 rpm, then dried to thereby form an organic layer having a thickness of 70 nm.

Next, laser light was applied to the organic layer on the silicon substrate by means of NEO 1000 (manufactured by Pulstec Industrial Co., Ltd.) at the conditions of 5 m/s and 5 mW, and at the pitch of 700 nm in the circumferential direction. As a result, the substrate having the organic layer which had concave portions formed in the surface thereof was obtained.

The silicon substrate was then dry etched using the organic layer to which the convex-concave portion had been formed as a mask, to thereby form concave portions each having a depth of 200 nm on the silicon substrate. The remained organic layer on the silicon substrate was dissolved and removed by 2,2,3,3-tetrafluoro-1-propanol. Note that, the conditions for the dry etching were such that a reactive ion etching (RIE) was performed using SF6 gas, at an output of 150 W for 25 seconds. In the manner mentioned above, an imprint mold was prepared.

Next, a photocurable resin (PAK01, manufactured by Toyo Gosei Co., Ltd.) was applied onto a polycarbonate substrate having a thickness of 80 μm to thereby form an imprint layer having a thickness of 10 μm.

The previously prepared imprint mold was pressed against the imprint layer on the polycarbonate substrate, and in this condition the imprint layer was cured with UV light so as to transfer the convex-concave pattern of the imprint mold to the imprint layer. Then, the imprint mold was released from the imprint layer to thereby prepare a convex-concave portion on the polycarbonate substrate (Convex-concave portion forming step).

The convex-concave portion formed on the polycarbonate substrate was observed under a scanning electron microscope (SEM), and it was found that in FIG. 1, a pitch P was 700 nm, a flat width a of the convex portion was 200 nm, a width b of the slant portion was 150 nm, a flat width c of the bottom part was 200 nm, a height d of the convex portion was 100 nm, and a slant angle θ of the slant portion was 34 degrees.

Next, the polycarbonate substrate to which the convex-concave portion had been formed was cut into ¼, and the polycarbonate substrate to whose surface the convex-concave portion had been formed was placed so that the side of the polycarbonate substrate where the concave-convex portion was present faces the side from where a vacuum deposition was applied, and then the vacuum deposition was performed using silver as a conductive material at an angle θ1 of 16 degrees with respect to the vertical direction of the substrate. Auxiliary electrode layers each having a thickness of 20 nm were formed at least on the slant portions of the convex-concave portion (Auxiliary electrode layer forming step).

The auxiliary electrode layer on the slant face had an angle of 34 degrees with respect to the vertical direction of the substrate.

Thereafter, onto the surfaces of the convex-concave portion and the auxiliary electrode layers, a conductive polymer solution (Baytron P, manufactured by H. C. Starck) was spin-coated at 1,000 rpm, and dried, to thereby form a transparent conductive layer having a thickness of 100 nm to 200 nm (Transparent conductive layer forming step). In the manner mentioned above, a transparent conductor of Example 3 was prepared.

### Example 4

A transparent conductor of Example 4 was prepared in the same manner as in Example 1, provided that laser light was applied to the organic layer on the silicon substrate by means of NEO 1000 (manufactured by Pulstec Industrial Co., Ltd.) at the conditions of 5 m/s and 3 mW, and at the pitch of 500 nm in the circumferential direction, and the polycarbonate substrate to whose surface the convex-concave portion had been formed was placed so that the side of the polycarbonate substrate where the concave-convex portion was present faces the side from where a vacuum deposition was applied, and then the vacuum deposition was performed using silver as a conductive material at an angle θ1 of 22 degrees with respect to the vertical direction of the substrate.

The convex-concave portion formed on the polycarbonate substrate was observed under a scanning electron microscope (SEM), and it was found that in FIG. 1, a pitch P was 500 nm, a flat width a of the convex portion was 0 nm, a width b of the slant portion was 120 nm, a flat width c of the bottom part was 260 nm, a height d of the convex portion was 150 nm, and a slant angle θ of the slant portion was 51 degrees.

The auxiliary electrode layer on the slant face had an angle of 51 degrees with respect to the vertical direction of the substrate.

### Example 5

A transparent conductor of Example 5 was prepared in the same manner as in Example 1, provided that laser light was applied to the organic layer on the silicon substrate by means of NEO 1000 (manufactured by Pulstec Industrial Co., Ltd.) at the conditions of 5 m/s and 3 mW, and at the pitch of 500 nm in the circumferential direction; the conditions of the dry etching were such that reactive ion etching (RIE) was performed using SF6 gas, at output of 150 W for 50 seconds; and the polycarbonate substrate to whose surface the convex-concave portion had been formed was placed so that the side of the polycarbonate substrate where the concave-convex portion was present faces the side from where a vacuum deposition was applied, and then the vacuum deposition was performed using silver as a conductive material at an angle θ1 of 28 degrees with respect to the vertical direction of the substrate.

The convex-concave portion formed on the polycarbonate substrate was observed under a scanning electron microscope (SEM), and it was found that in FIG. 1, a pitch P was 500 nm, a flat width a of the convex portion was 0 nm, a width b of the slant portion was 120 nm, a flat width c of the bottom part was 260 nm, a height d of the convex portion was 200 nm, and a slant angle θ of the slant portion was 59 degrees.

The auxiliary electrode layer on the slant face had an angle of 59 degrees with respect to the vertical direction of the substrate.

### Example 6

A transparent conductor of Example 6 was prepared in the same manner as in Example 1, provided that laser light was applied to the organic layer on the silicon substrate by means of NEO 1000 (manufactured by Pulstec Industrial Co., Ltd.) at the conditions of 5 m/s and 6 mW, and at the pitch of 500 nm in the circumferential direction, and the polycarbonate substrate to whose surface the convex-concave portion had been formed was placed so that the side of the polycarbonate substrate where the concave-convex portion was present faces the side from where a vacuum deposition was applied, and then the vacuum deposition was performed using silver as a conductive material at an angle θ1 of 10 degrees with respect to the vertical direction of the substrate.

The convex-concave portion formed on the polycarbonate substrate was observed under a scanning electron microscope (SEM), and it was found that in FIG. 1, a pitch P was 500 nm, a flat width a of the convex portion was 200 nm, a width b of the slant portion was 150 nm, a flat width c of the bottom part was 0 nm, a height d of the convex portion was 150 nm, and a slant angle θ of the slant portion was 45 degrees.

The auxiliary electrode layer on the slant face had an angle of 45 degrees with respect to the vertical direction of the substrate.

### Example 7

A transparent conductor of Example 7 was prepared in the same manner as in Example 1, provided that laser light was applied to the organic layer on the silicon substrate by means of NEO 1000 (manufactured by Pulstec Industrial Co., Ltd.) at the conditions of 5 m/s and 6 mW, and at the pitch of 500 nm in the circumferential direction, and the polycarbonate substrate to whose surface the convex-concave portion had been formed was placed so that the side of the polycarbonate substrate where the concave-convex portion was present faces the side from where a vacuum deposition was applied, and then the vacuum deposition was performed using silver as a conductive material at an angle θ1 of 45 degrees with respect to the vertical direction of the substrate.

The convex-concave portion formed on the polycarbonate substrate was observed under a scanning electron microscope (SEM), and it was found that in FIG. 1, a pitch P was 500 nm, a flat width a of the convex portion was 200 nm, a width b of the slant portion was 150 nm, a flat width c of the bottom part was 0 nm, a height d of the convex portion was 150 nm, and a slant angle θ of the slant portion was 45 degrees.

The auxiliary electrode layer on the slant face had an angle of 45 degrees with respect to the vertical direction of the substrate.

### Comparative Example 1

A transparent conductor of Comparative Example 1 was prepared in the same manner as in Example 1, provided that vacuum deposition was performed on a polycarbonate substrate to whose surface no convex-concave portion was present without a mask, at an angle of 90 degrees with respect to the vertical direction of the substrate.

Transparent conductors of Examples 1 to 7, and Comparative Example 1 were evaluated in terms of transmittance, resistance, and light output efficiency when attached to a light. The results are shown in Table 1.

### <Transmittance>

The transmittance was measured by means of USB 2000 manufactured by Ocean Photonics Co., Ltd.

### <Resistance>

The resistance was measured by means of a multimeter 289 manufactured by Fluka Corporation.

<Light Output Efficiency when Attached with a Light>

Each transparent conductor was attached to a fluorescent light, and a quantity of the output light was measured by USB 2000 manufactured by Ocean Photonics Co., Ltd. The quantity is expressed relative to 100 that is the quantity of the output light of the fluorescent light without the transparent electrode.

TABLE 1

| | Ex. 1 | Ex. 2 | Ex. 3 | Ex. 4 | Ex. 5 | Ex. 6 | Ex. 7 | Com. Ex. 1 |
|---|---|---|---|---|---|---|---|---|
| Heat mode Material | 1 | 2 | 3 | 1 | 1 | 1 | 1 | — |
| Power (mW) | 4 | 6 | 5 | 3 | 3 | 6 | 6 | — |
| RIE duration (s) | 40 | 40 | 25 | 40 | 50 | 40 | 40 | — |
| Pitch: P (nm) | 500 | 600 | 700 | 500 | 500 | 500 | 500 | — |
| flat width of | 50 | 100 | 200 | 0 | 0 | 200 | 200 | — |
| convex portion: | | | | | | | | |
| a (nm) | | | | | | | | |
| Ratio | 10% | 16.7% | 28.6% | 0% | 0% | 40% | 40% | — |
| [(a/P) × 100] | | | | | | | | |
| Slant portion | 150 | 150 | 150 | 120 | 120 | 150 | 150 | — |
| width: b (nm) | | | | | | | | |
| Flat width of | 150 | 200 | 200 | 260 | 260 | 0 | 0 | — |
| bottom part: c | | | | | | | | |
| (nm) | | | | | | | | |
| Height of convex | 150 | 150 | 100 | 150 | 200 | 150 | 150 | — |
| portion: d (nm) | | | | | | | | |
| Slant angle: θ (°) | 45 | 45 | 34 | 51 | 59 | 45 | 45 | — |
| Deposition | Ag | Ag | Ag | Ag | Ag | Ag | Ag | Ag |
| material | | | | | | | | |
| Thickness of auxiliary | 20 | 20 | 20 | 20 | 20 | 20 | 20 | 20 |
| electrode layer (nm) | | | | | | | | |
| Deposition angle (°) | 27 | 23 | 16 | 22 | 28 | 10 | 45 | 90 |
| Transmittance (%) | 68 | 66 | 55 | 77 | 78 | 55 | 45 | 35 |
| Resistance (Ω/sq.) | 7 | 7 | 7 | 7 | 7 | 6 | 5 | 4 |
| Light output | 140 | 130 | 110 | 150 | 160 | 60 | 90 | 40 |
| efficiency when | | | | | | | | |
| attached to a light | | | | | | | | |

The transparent conductor of the present invention can be widely applied, such as a use as a transparent electrode for a liquid crystal display, a plasma display, an electroluminescence display, an electrochromic display, a solar battery, and a touch panel, a use as an electronic paper, and a use as a shielding material for electromagnetic waves.

What is claimed is:

1. A transparent conductor, comprising:
a convex-concave portion formed on a surface of a base such that a plurality of concave portions are aligned based on the surface;
an auxiliary electrode layer formed of a conductive material, and provided at least on slant faces of the convex-concave portion; and
a transparent conductive layer formed on surfaces of the convex-concave portion and the auxiliary electrode layer.

2. The transparent conductor according to claim 1, wherein the auxiliary electrode layer provided on the slant faces makes an acute angle of 0 degree to 45 degrees with respect to a vertical direction of the transparent conductor.

3. The transparent conductor according to claim 1, wherein a cross-sectional shape of the convex-concave portion is asymmetric.

4. The transparent conductor according to claim 1, wherein a planar shape of the convex-concave portion is either lines or a lattice.

5. The transparent conductor according to claim 1, wherein the transparent conductor satisfies the relationship: [(a/P)×100]≦50%, where a represents a flat width of the convex portion, and P represents a minimum distance between two convex portions adjacent to each other.

6. The transparent conductor according to claim 1, wherein the transparent conductive layer contains a conductive polymer.

7. A method for producing a transparent conductor, comprising:
aligning a plurality of convex portions based on a surface of a base so as to form a convex-concave portion on the surface of the base;
forming an auxiliary electrode layer formed of a conductive material at least on slant faces of the convex-concave portion; and
forming a transparent conductive layer on surfaces of the convex-concave portion and the auxiliary electrode layer.

8. The method for producing a transparent conductor according to claim 7, wherein the aligning comprises providing on the surface of the base an organic layer capable of changing a shape thereof in a heat mode, and exposing the organic layer to condensed light, so as to form the convex-concave portion.

9. The method for producing a transparent conductor according to claim 7, wherein the aligning comprises providing an imprint layer on the surface of the base, and pressing an imprint mold against the imprinting layer, so as to form the convex-concave portion in accordance with an imprint method.

10. The method for producing a transparent conductor according to claim 9, wherein the imprint mold is formed by etching through a mask, and the mask is an organic layer capable of changing a shape thereof in a heat mode and is provided with a convex-concave portion by being exposed to condensed light.

11. The method for producing a transparent conductor according to claim 7, wherein the formation of the auxiliary electrode layer is carried out by a vacuum deposition, and the vacuum deposition is carried out at an angle of 1 degree to 80 degrees with respect to a vertical direction of the base, with the base being placed so as to subject a side of the base where the convex-concave portion has been formed to the vacuum deposition
